(19) United States
(12) Patent Application Publication
(10) Pub. No.: US 2004/0262774 A1
(43) Pub. Date: Dec. 30, 2004

(54) Multi-chip packages having a plurality of flip chips and methods of manufacturing the same

(76) Inventors: In-Ku Kang, Cheonan-si (KR); Jin-Ho Kim, Suwon-si (KR); Sang-Ho An, Suwon-si (KR)

Correspondence Address: HARNESS, DICKEY & PIERCE, P.L.C., P.O. BOX 8910, RESTON, VA, 20195, US

(21) Appl. No.: 10/870,152

(22) Filed: Jun. 18, 2004

(30) Foreign Application Priority Data
Jun. 27, 2003 (KR) 2003-42730

(51) Int. Cl. H01L 23/02

(52) U.S. Cl. 257/777

(57) ABSTRACT

Multi-chip packages having at least two flip chips and methods of manufacturing the same are provided. The multi-chip packages may include a printed circuit board having a substrate and a plurality of interconnection lines formed on a front surface of the substrate. The at least two flip chips may be stacked on the front surface of the substrate. The flip chips may be stacked so that pads of the flip chips face the printed circuit board. A first group of bumps may be interposed between the pads of the first flip chip and a first group of interconnection lines of the plurality of lines. Further, a second group of bumps may be interposed between the pads of the at least one upper flip chip and a second group of interconnection lines of the plurality of lines.

### CROSS-REFERENCE TO RELATED APPLICATION

This application claims the benefit of priority of Korean Patent Application No. 2003-0042730, filed Jun. 27, 2003, the contents of which are herein incorporated by reference in their entirety.

### BACKGROUND OF THE INVENTION

1. Field of the Invention

The present invention relates to semiconductor packages and, more particularly, to multi-chip packages having a plurality of flip chips and methods of manufacturing the same.

2. Description of the Related Art

As portable electronic devices become smaller, semiconductor packages mounted in the portable electronic devices have been also become smaller. Further, a technique for mounting a plurality of semiconductor chips in a single semiconductor package, e.g., a multi-chip package technique has been used in order to increase the capacity of the package.

FIG. 1 is a sectional view illustrating a conventional multi-chip package. Referring to FIG. 1, a lower chip 3 and an upper chip 5 may be stacked on a printed circuit board 1. A back surface of the lower chip 3 may contact a top surface of the printed circuit board 1 via an adhesive 7, and a back surface of the upper chip 5 may contact a top surface of the lower chip 3 via an adhesive 9. In this case, a width of the upper chip 5 may be less than that of the lower chip 3 in order to expose pads formed on an edge of the lower chip 3, as shown in FIG. 1.

The pads of the lower chip 3 and the pads of the upper chip 5 may be electrically connected to interconnection lines 13 formed on an edge of the printed circuit board 1 through a first group of bonding wires 11 and a second group of bonding wires 15, respectively.

The multi-chip package shown in FIG. 1 may employ conventional bonding wires to electrically connect the upper chip 5 and the lower chip 3 to the lines 13 on the printed circuit board 1. That is, the second group of bonding wires 15 may be extend to a higher level than the upper chip 5. Thus, there may be a limitation in reducing a thickness of an epoxy molding compound for encapsulating the bonding wires 11 and 15 as well as the chips 3 and 5. In addition, the bonding wires may act as inductors and/or resistors to degrade high frequency characteristics of the chips 3,5.

FIG. 2 is a perspective view illustrating another conventional multi-chip package and FIG. 3 is a vertical sectional view taken along a line that passes through central portions of the lower chip and the upper chip shown in FIG. 2.

Referring to FIGS. 2 and 3, a lower chip 23 and an upper chip 25 may be sequentially stacked on a printed circuit board 21. The upper chip 25 may be placed to cross over the lower chip 23, for example, as shown in FIG. 2, the lower chip 23 and the upper chip 25 may be substantially perpendicular. The lower chip 23 may have the same size and/or function as the upper chip 25. A back surface of the lower chip 23 may contact a top surface of the printed circuit board 21 through an adhesive 22, and a back surface of the upper chip 25 may contact a top surface of the lower chip 23 through an adhesive 27. In this case, the length of the upper chip 25 may be greater than the width of the lower chip 23 as shown in FIGS. 2 and 3. Thus, the upper chip 25 may have “overhangs”, e.g., both ends that do not overlap the lower chip 23.

Pads formed on ends of the lower chip 23 may be electrically connected to a first group of lines 31 formed on an edge of the printed circuit board 21 through a first group of bonding wires 29. Similarly, pads formed on ends of the upper chip 25 may be electrically connected to a second group of lines 35 formed on an edge of the printed circuit board 21 through a second group of bonding wires 33. A conventional bonding wire head 41 shown in FIG. 3 may be used in order to form the first and second groups of bonding wires 29 and 33. The bonding wire head 41 may hold a bonding wire 43.

The head 41 may be moved down toward the pads in order to form the bonding wires 29 and 33. As a result, the wire 43 held by the head 41 contacts a pad and pressure may be applied to the pad. The overhangs may be warped during formation of the second group of bonding wires 33 as indicated by the arrows in FIG. 3. Warpage of the overhangs may cause the contact of the second group of bonding wires 33 to fail. The longer the overhang is, the greater the contact fail rate of the second group of bonding wires 33 may be.

Japanese Laid-open Patent No. 06-302645 discloses a method of connecting a light-emitting device to a light-receiving device. According to Japanese Laid-open Patent No. 06-302645, a light-emitting device substrate is mounted on a light-receiving device substrate. The light-receiving device substrate has light-receiving devices formed on a surface thereof and the light-emitting device substrate has light-emitting devices formed on a surface thereof. The light-emitting device substrate is mounted over the light-receiving device substrate so that the light-emitting devices and the light-receiving devices face each other. That is, the light-emitting device substrate is flipped and located over the light-receiving device substrate. Transparent spacers may be interposed between the light-receiving device substrate and the light-emitting device substrate. Thus, the light-emitting devices are spaced apart from the light-receiving devices. Further, interconnection lines on the light-receiving device substrate are electrically connected to interconnection lines on the light-emitting device substrate through a plurality of stacked bumps.

### SUMMARY OF THE INVENTION

Exemplary embodiments of the present invention provide thinner and/or more compact multi-chip packages.

In exemplary embodiments of the present invention, a multi-chip package may include a printed circuit board including a substrate having an upper surface and a lower surface, at least two chips including a first chip and a second chip. At least a first and a second plurality of interconnection lines may be formed on the upper surface. The first chip may be mounted on the upper surface of the substrate and a first plurality of bumps may be interposed between the pads of the first chip and the first plurality of interconnection lines. The second chip may be mounted on the first chip. A second plurality of bumps may be interposed between the plurality of pads of the second chip and the second plurality of interconnection lines.

In an exemplary embodiment of the present invention, each of the first plurality of bumps may be a single stud bump.

In an exemplary embodiment of the present invention, each of the second plurality of bumps is a single soldering bump.

In an exemplary embodiment of the present invention, each of the second plurality of bumps may include a plurality of stacked stud bumps.

In an exemplary embodiment of the present invention, the second chip may be stacked to cross over the first chip.

In an exemplary embodiment of the present invention, the second chip may have a size greater than the first chip.

In an exemplary embodiment of the present invention, an epoxy resin may encapsulate the at least two chips and the printed circuit board. In another exemplary embodiment of the present invention, an epoxy molding compound may encapsulate the at least two chips and the printed circuit board and may cover the second chip. Thus, an upper multi-chip package may be formed. In another exemplary embodiment of the present invention, a lower multi-chip package may be formed on the lower surface of the substrate. The lower multi-chip package may have same configuration as the upper multi-chip package.

In an exemplary embodiment of the present invention, a third chip may be formed on the second chip and have pads formed on a surface opposite to the at least two chips. A plurality of bonding wires may connect the pads and a third plurality of interconnection lines formed on the substrate. An epoxy molding compound may encapsulate the at least two chips, the third chip and the bonding wires. Thus, an upper multi-chip may be formed. In another exemplary embodiment, a lower multi-chip package may be formed on the lower surface of the substrate and may have the same configuration as the upper multi-chip package.

In an exemplary embodiment of the present invention, a height of the second group of bumps is greater than a sum of the height of the first group of bumps and a height of the lower flip chip.

Other exemplary embodiments are directed to methods for manufacturing the various multi-chip packages of the present invention.

### BRIEF DESCRIPTION OF THE DRAWINGS

The above and/or other features of the present invention will become readily apparent by from the description of the exemplary embodiments that follows with reference to the attached drawings in which:

FIG. 1 is a sectional view illustrating a conventional multi-chip package.

FIG. 2 is a perspective view illustrating another conventional multi-chip package.

FIG. 3 is a sectional view to illustrate other aspects of the conventional multi-chip package shown in FIG. 2.

FIG. 4 is a sectional view illustrating a multi-chip package according to an exemplary embodiment of the present invention.

FIG. 5 is a sectional view illustrating a multi-chip package according to another exemplary embodiment of the present invention.

FIG. 6 is a sectional view illustrating a multi-chip package according to another exemplary embodiment of the present invention.

FIG. 7 is a perspective view illustrating an example of stack configurations of the flip chips according to an exemplary embodiment shown in FIGS. 4 to 6.

FIGS. 8 to 12 are sectional views to illustrate methods of fabricating the multi-chip package of FIG. 4.

FIG. 13 is a sectional view to illustrate methods of fabricating the multi-chip package of FIG. 5.

FIG. 14 is a sectional view to illustrate methods of fabricating the multi-chip package of FIG. 6.

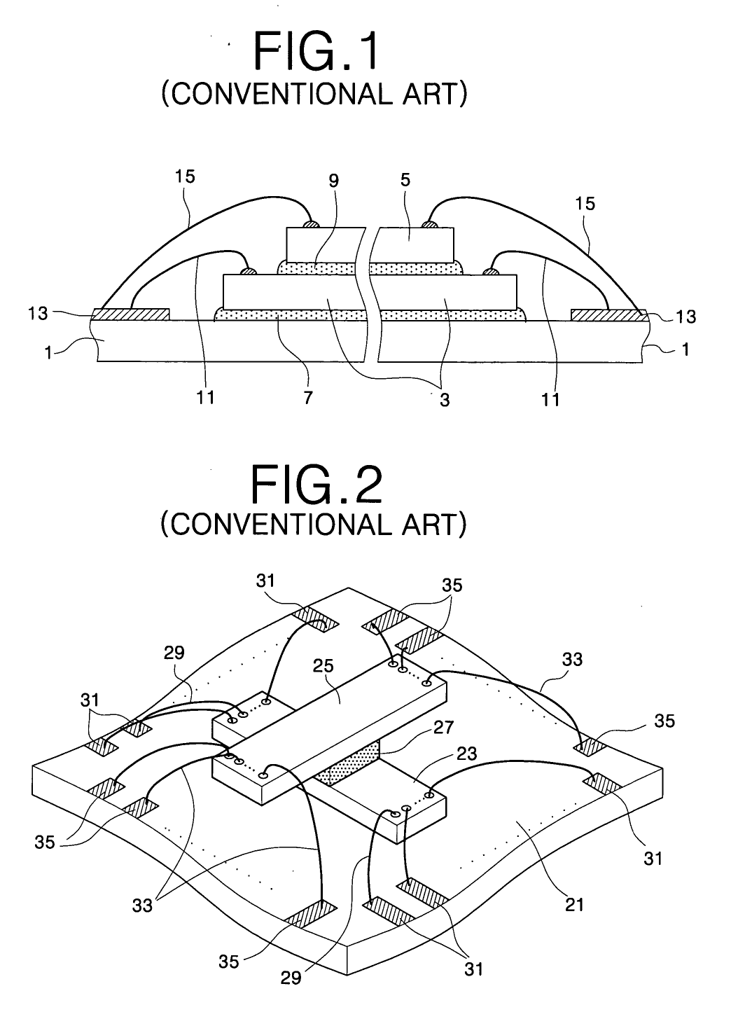

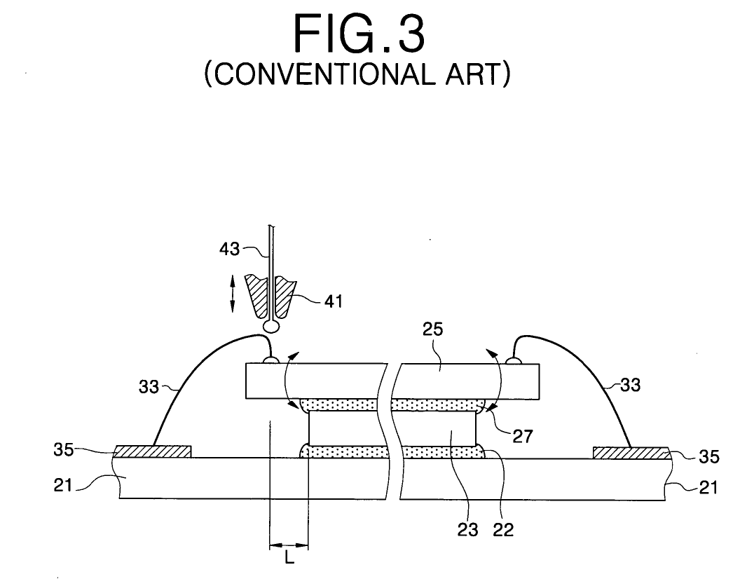

### DETAILED DESCRIPTION OF EXEMPLARY EMBODIMENTS OF THE INVENTION

The present invention will now be described more fully hereinafter with reference to the accompanying drawings, in which exemplary embodiments of the invention are shown. However, the present invention may be embodied in different forms and should not be construed as limited to the exemplary embodiments set forth herein. Rather, these exemplary embodiments are provided for the purpose of illustration; the present invention covers various changes in form and details as will be readily contemplated by those ordinarily skilled in the art.

It should also be noted that the thickness of various layers and regions in the stacked package have been exaggerated in the drawings for the purpose of clarity and the same drawing reference numerals are used for the same elements even in different drawings.

It should also be noted that a layer is considered as being formed “on” another layer or substrate when formed either directly on the referenced layer or the substrate or formed on other layers or patterns overlaying the referenced layer.

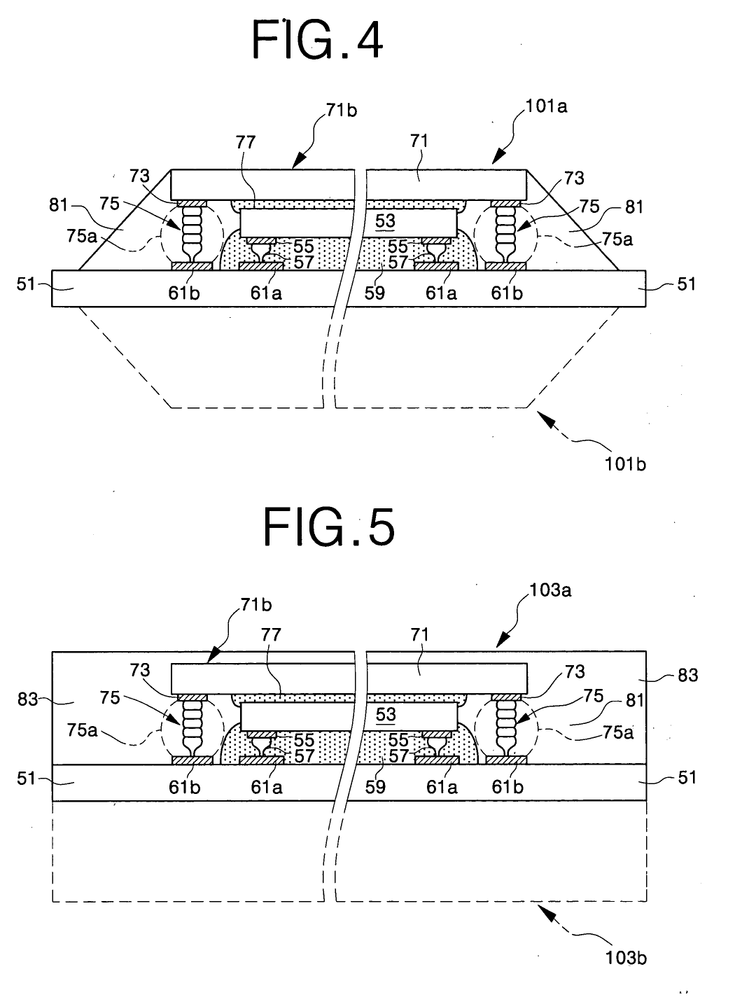

FIG. 4 is a sectional view illustrating a multi-chip package according to an exemplary embodiment of the present invention.

Referring to FIG. 4, a lower flip chip 53 and an upper flip chip 71 may be sequentially stacked on a front surface of a printed circuit board. The printed circuit board may include a flat substrate 51, a first group of lines 61a, and/or a second group of lines 61b, with both groups of lines formed on a front surface of the substrate 51. The lower flip chip 53 may include pads 55 facing the printed circuit board. Similarly, the upper flip chip 71 may also include pads 73 facing the printed circuit board. Thus, integrated circuits may be provided on a main surface of the flip chip 53 between the pads 55, and other integrated circuits may be also provided on a main surface of the flip chip 71 between the pads 73. The pads 55 may be placed over the first group of lines 61a, and the pads 73 may be placed over the second group of lines 61b.

In an exemplary embodiment, the upper flip chip 71 may have a size greater than that of the lower flip chip 53 as shown in FIG. 4. In other words, the upper flip chip 71 may have a greater width and/or a greater length than the lower flip chip 53. Also, the upper flip chip 71 may have a different function from the lower flip chip 53. A first group of bumps 57 may be provided between the pads 55 and the first group of lines 61a. Each of the first group of bumps 57 may be a single stud bump. The stud bumps 57 may be fabricated on the pads 55 using a conventional wire bonding technique. As a result, the pads 55 may be electrically connected to the first group of lines 61a through the first group of bumps 57.

A second group of bumps may be provided between the pads 73 and the second group of lines 61b. Each of the second group of bumps may be composed of a plurality of stud bumps 75 which are sequentially stacked. Alternatively, the second group of bumps may be a single soldering bump 75a with a height greater than the stud bump or stud bump(s) 57. The number of bumps in each of the stacked stud bumps 75 may be determined by the distance between the upper flip chip 71 and the second group of lines 61b or the printed circuit board. The stacked stud bumps 75 may also be fabricated on the pads 73 using a conventional wire bonding technique. As a result, the pads 73 may be electrically connected to the second group of lines 61b through the second group of bumps 75 or 75a.

A space between the upper flip chip 71 and the printed circuit board 51 may be filled with epoxy resin 81. In an exemplary embodiment, a back surface (71b of FIG. 4) of the upper flip chip 71 may be exposed, and the epoxy resin 81 encapsulates the bumps 57, 75, and/or 75a, and the lower flip chip 53. In addition, an adhesive 59 may be interposed between the lower flip chip 53 and the printed circuit board 51. Similarly, an adhesive 77 may be interposed between the flip chips 53 and 71.

The flip chips 53 and 71, the bumps 57, 75 and 75a, and the epoxy resin 81 may constitute an upper multi-chip package 101a. Further, a lower multi-chip package 101b may be attached to a bottom surface of the printed circuit board. The lower multi-chip package 101b may have the same configuration as the upper multi-chip package 101a.

According to the exemplary embodiment discussed above, a plurality of flip chips may be mounted on the printed circuit board. Thus, the thickness of the multi-chip package according to the present invention may be reduced as compared to the conventional multi-chip package.

FIG. 5 is a sectional view illustrating multi-chip packages according to another exemplary embodiment of the present invention.

Referring to FIG. 5, the multi-chip package according to an exemplary embodiment may include a printed circuit board 51, flip chips 53 and 71, and bumps 57, 75 and/or 75a having the same structure and configuration as described with reference to FIG. 4. The flip chips 53 and 71, and the bumps 57, 75 and/or 75a may be completely covered with an epoxy molding compound 83 having a different configuration from the epoxy resin 81 shown in FIG. 4. That is, the back surface 71b of the upper flip chip 71 may also be covered with the epoxy molding compound 83. The adhesive 77 may be interposed between the flip chips 53 and 71 and the adhesive 59 may be interposed between the lower flip chip 53 and the printed circuit board 51. The epoxy molding compound 83, the flip chips 53 and 71, and the bumps 57, 75 and/or 75a may constitute an upper multi-chip package 103a. Further, a lower multi-chip package 103b may be attached to the bottom surface of the printed circuit board similar to the embodiments illustrated in FIG. 4. The lower multi-chip package 103b may have the same configuration as the upper multi-chip package 103a.

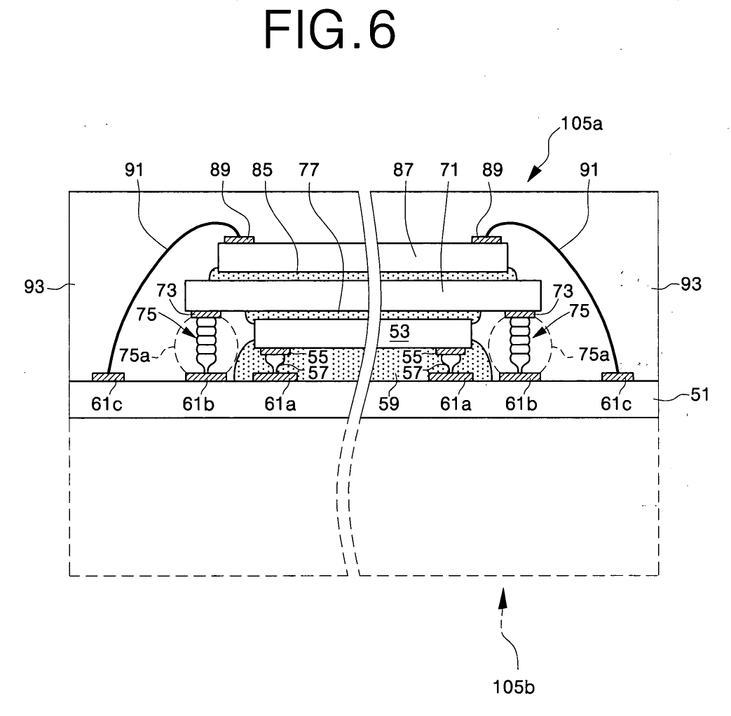

FIG. 6 is a sectional view illustrating multi-chip packages according to another exemplary embodiment of the present invention.

Referring to FIG. 6, the multi-chip package may include flip chips 53 and 71, and bumps 57, 75 and/or 75a having the same structure and configuration as described in the exemplary embodiment illustrated with reference to FIG. 4. The flip chips 53 and 71 and the bumps 57, 75 and/or 75a may be stacked on a printed circuit board 51. The printed circuit board 51 may include a third group of interconnection lines 61c in addition to the first and second group of interconnection lines 61a and 61b illustrated in FIG. 4.

A third chip 87 may be stacked on the upper flip chip 71. The third chip 87 may have pads 89 provided on the surface opposite to the flip chips 53 and 71. The pads 89 may be electrically connected to the third group of lines 61c through bonding wires 91. An adhesive 85 may be interposed between the upper flip chip 71 and the third chip 87. The flip chips 53 and 71, the third chip 87, the bumps 57, 75 and/or 75a, and the bonding wires 91 may be completely encapsulated with epoxy molding compound 93. The epoxy molding compound 93, the flip chips 53 and 71, the third chip 87, the bumps 57, 75 and/or 75a, and the bonding wires 91 may constitute an upper multi-chip package 105a. Further, a lower multi-chip package 105b may be attached to a bottom surface of the printed circuit board similar to the embodiments described with reference to FIGS. 4 and 5. The lower multi-chip package 105b may have the same configuration as the-upper multi-chip package 105a.

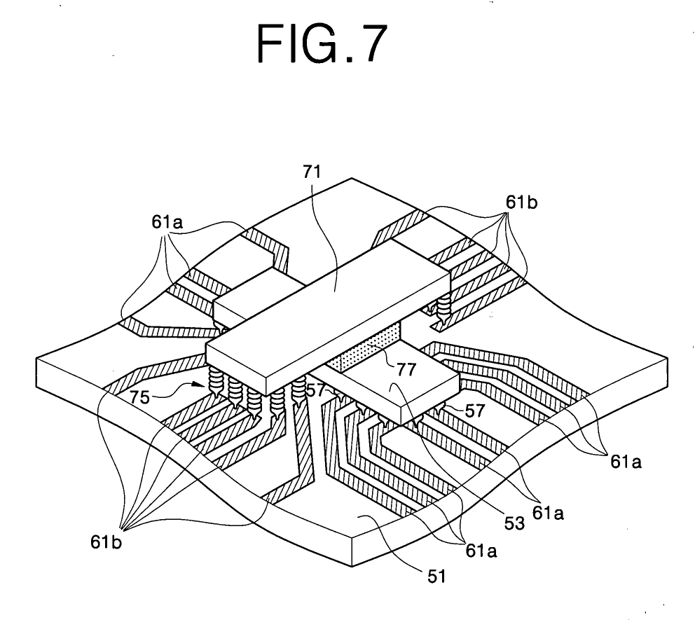

FIG. 7 is a perspective view illustrating an exemplary embodiment of the stack configurations of the flip chips shown in FIG. 4 to 6.

Referring to FIG. 7, the lower flip chip 53 may be stacked on the printed circuit board, and the upper flip chip 71 may be stacked on the lower flip chip 53. From a top plan view, the lower flip chip 53 and the upper flip chip 71 may have rectangular shapes. The lower flip chip 53 and the upper flip chip 71 may have any arrangement which creates an overhang between the lower flip chip 53 and the upper flip chip. In particular, the length of the upper flip chip 71 may be greater than the width of the lower flip chip 53. In an exemplary embodiment, the upper flip chip 71 may be stacked to cross over the lower flip chip 53 as shown in FIG. 7. As a result, both ends of the upper flip chip 71 do not overlap the lower flip chip 53. Both ends of the upper flip chip 71 may be called overhangs. The second group of bumps 75 may be interposed between the overhangs and the second group of lines 61b, thereby supporting the overhangs.

Methods of fabricating multi-chip packages according to exemplary embodiments of the present invention will be described hereinafter.

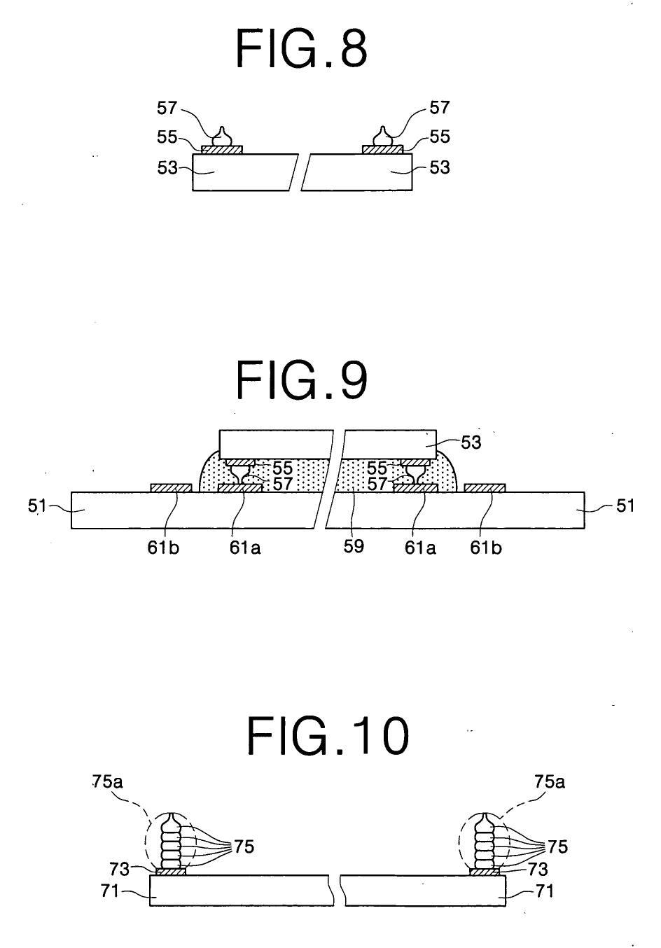

FIGS. 8 to 12 are sectional views to illustrate methods of fabricating the multi-chip package shown in FIG. 4.

Referring to FIG. 8, a first chip 53 having pads 55 may be provided. A first group of bumps 57 may be formed on the pads 55 using a conventional wire bonding technique. Each of the first bumps 57 may be a single stud bump. The first bumps 57 may be formed, for example, using gold (Au) wires.

Referring to FIG. 9, a printed circuit board may also be provided. The printed circuit board may include a substrate 51, a first group of interconnection lines 61a, and a second group of interconnection lines 61b formed on a front surface of the substrate 51. Ends of the first group of lines 61a may be located at positions that correspond to one or more of the pads 55. The first chip 53 having the first group of bumps 57 may be mounted on the substrate 51. In an exemplary embodiment, the first chip 53 may be flipped so that the first bumps 57 face the substrate 51. That is, the first chip 53 may correspond to a lower flip chip. Further, the lower flip chip 53 may be arranged so that the first bumps 57 are in contact with the corresponding first lines 61a, respectively. The first bumps 57 may be bonded to the first lines 61a using, for example, an ultrasonic chip bonding apparatus. In an exemplary embodiment, the first bumps 57 may be composed of gold (Au) and the first and second group of lines 61a and 61b may be coated with gold (Au). In particular, when copper (Cu) lines are used as the first and second group of lines 61a and 61b, the copper lines may be coated with nickel and a surface of the nickel layer may be coated with gold. This may facilitate contact and bonding between the first group of bumps 57 and the first group of lines 61a.

An adhesive 59 may be provided on the printed circuit board before mounting the lower flip chip 53 on the printed circuit board. In an exemplary embodiment, the adhesive 59 may fill the space between the lower flip chip 53 and the printed circuit board. In this way, the adhesion between the lower flip chip 53 and the printed circuit board may be increased.

Referring to FIG. 10, a second chip 71 having pads 73 may be provided. The second chip 71 may have a larger planar area than that of the lower flip chip 53. A second group of bumps 75 may be formed on the pads 73 using a conventional wire bonding technique. Each of the second bumps 75 may be formed by stacking a plurality of stud bumps. That is, the second bumps 75 may be formed to be higher than the first bumps 57. More specifically, the height of the second bumps 75 may be greater than the sum of the height of the first bumps 57 and the thickness of the lower flip chip 53. Alternatively, each of the second bumps 75 may be formed of a single soldering bump 75a instead of stacked stud bumps. In an exemplary embodiment, the height of the single soldering bumps 75a may also be greater than the sum of the height of the first bumps 57 and the thickness of the lower flip chip 53.

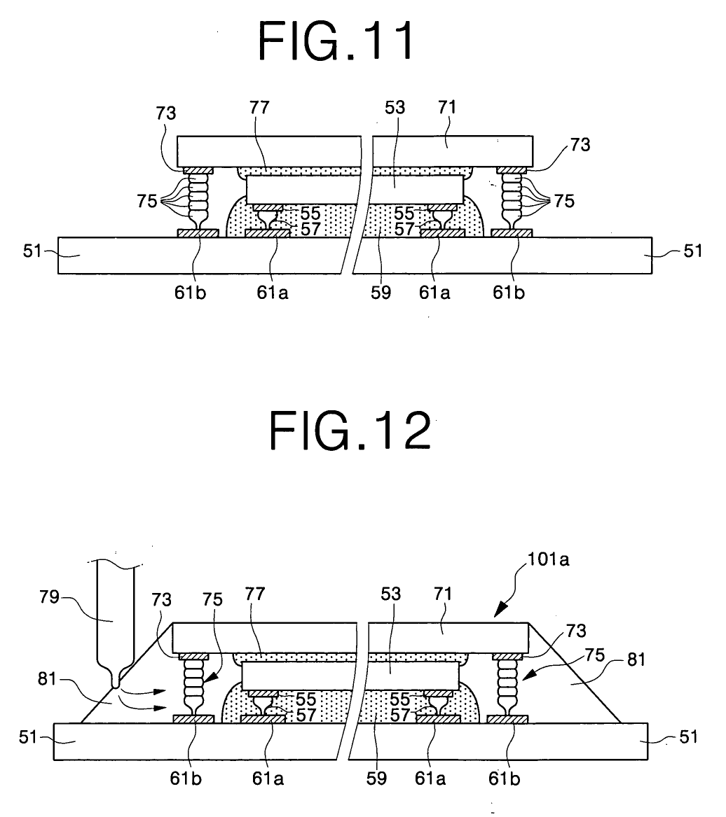

Referring to FIG. 11, the second chip 71 having the second bumps 75 and/or 75a may be mounted on the printed circuit board, e.g., the lower flip chip 53. In an exemplary embodiment, the second chip 71 may be flipped so that the second bumps 75 or 75a face the substrate 51. Accordingly, the second chip 71 may correspond to an upper flip chip. Further, the upper flip chip 71 may be arranged so that the second bumps 75 or 75a contact the corresponding second lines 61b, respectively. The second bumps 75 or 75a may be bonded to the second lines 61b using, for example, an ultrasonic chip bonding apparatus.

In the event that the upper flip chip 71 has the same rectangular shape as the lower flip chip 53 when viewed from the top, the upper flip chip 71 may be mounted to cross the lower flip chip 53, or otherwise create an overhang, as shown in FIG. 7. In an exemplary embodiment, both ends of the upper flip chip 71 create overhangs that do not overlap the lower flip chip 53. According to this embodiment, the second bumps 75 or 75a may support the overhangs. In other words, there may be no need to form bonding wires on the overhangs. Accordingly, contact failures of the bonding wires may be reduced.

An adhesive 77 may be supplied on the lower flip chip 53 to mount the upper flip chip 71 on the lower flip chip 53. In an exemplary embodiment, the adhesive 77 may fill the space between the upper flip chip 71 and the lower flip chip 53, when the upper flip chip 71 is mounted and bonded. In this way, the adhesion between the flip chips 53 and 71 may be increased.

In addition, the adhesives 59 and 77 may reduce the likelihood or prevent the lower flip chip 53 from warping. Warpage of the lower flip chip 53 may be caused by a stress of a polyimide layer formed on a front surface of the lower flip chip 53. If the thickness of the polyimide layer is increased, the stress applied to the lower flip chip 53 is also increased. Thus, the warpage of the lower flip chip 53 may be reduced or prevented by employing the adhesives 59 and 77 that fill the space between the lower flip chip 53 and the printed circuit board, as well as the space between the flip chips 53 and 77.

Referring to FIG. 12, the space between the upper flip chip 71 and the printed circuit board may be filled with an epoxy resin 81. The epoxy resin 81 may be supplied through a nozzle 79. As a result, the epoxy resin 81 may encapsulate the lower flip chip 53 and the bumps 57, 75 and/or 75a. In an exemplary embodiment, a back surface (71b of FIG. 4) of the upper flip chip 71 may be exposed. The epoxy resin 81, the flip chips 53 and 71, and the bumps 57, 75 and 75a may constitute an upper multi-chip package 101a.

According to exemplary embodiments described above, a plurality of flip chips may be stacked to reduce or minimize a thickness of the package. Further, the stacked chips may be electrically connected to the printed circuit board through the bumps. That is, exemplary embodiments of the present invention may not require formation of bonding wires that may cause high parasitic inductance and/or high resistance. Therefore, it may be possible to realize higher performance packages that are suitable for faster devices.

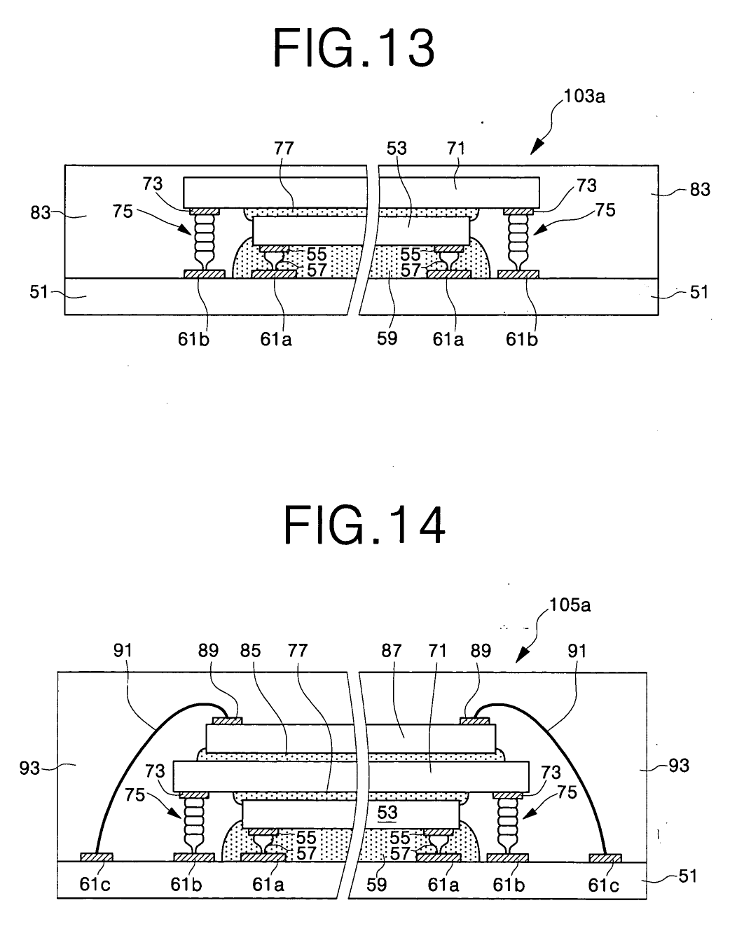

FIG. 13 is a sectional view to illustrate example methods of fabricating the multi-chip package shown in FIG. 5.

Referring to FIG. 13, a lower flip chip 53 and an upper flip chip 71 may be stacked on a printed circuit board using the same technique(s) as the exemplary embodiments described with reference to FIGS. 8 to 11. An epoxy molding compound 83 may be formed on a front surface of the printed circuit board to encapsulate the flip chips 53 and 71 and the bumps 57, 75, and/or 75a. The epoxy molding compound 83 may be formed to completely cover the upper flip chip 71. The epoxy molding compound 83, the flip chips 53 and 71, and bumps 57, 75 and/or 75a may constitute an upper multi-chip package 103a.

Exemplary embodiments similar to FIG. 13 may also provide methods of fabricating higher performance packages that are suitable for fast devices.

FIG. 14 is a sectional view to illustrate example methods of fabricating the multi-chip package shown in FIG. 6.

Referring to FIG. 14, a lower flip chip 53 and an upper flip chip 71 may be stacked on a printed circuit board in the same manner as the exemplary embodiments described with reference to FIGS. 8 to 11. The printed circuit board may include a third group of interconnection lines 61c in addition to the first and second group of interconnection lines 61a and 61b, as illustrated in FIG. 6. A third chip 87 may be mounted on the upper flip chip 71. The third chip 87 may have pads 89 formed on a surface opposite to the flip chips 53 and 71. An adhesive 85 may be provided on the upper flip chip 71 before mounting the third chip 87. Thus, the third chip 87 may be fixed on the upper flip chip 71 through the adhesive 85.

Bonding wires 91 for electrically connecting the pads 89 to the third lines 61c may be formed using, for example, a conventional wire bonding technique. In an exemplary embodiment, the third chip 87 may be a slower device that has a slower operation speed as compared to the flip chips 53 and 71. Therefore, the above exemplary embodiments of the present invention herein may be suitable for fabrication of a multi-chip package with devices of different speed, for example, a multi-chip package having both slower and faster devices.

An epoxy molding compound 93 may be formed on a front surface of the printed circuit board, thereby encapsulating the flip chips 53 and 71, the third chip 87, the bumps 57, 75, and/or 75a and the bonding wires 91. The epoxy molding compound 93, the flip chips 53 and 71, the third chip 87, the bumps 57, 75, and/or 75a and the bonding wires 91 may constitute an upper multi-chip package 105a.

As described above, according to the exemplary embodiments of the present invention, a plurality of flip chips are stacked on the printed circuit board. Therefore, in realization of a large capacity package, improved operation speed and/or a reduced thickness may be achieved.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A multi-chip package comprising:
a printed circuit board including a substrate and a plurality of interconnection lines formed on a front surface of the substrate;
a plurality of flip chips stacked on the front surface of the printed circuit board, the plurality of flip chips including a lowest flip chip that has pads facing the printed circuit board and at least one upper flip chip; and
a first group of bumps interposed between the pads of the lowest flip chip and first interconnection lines of the plurality of interconnection lines; and
a second group of bumps interposed between the pads of the at least one upper flip chip and second interconnection lines of the plurality of interconnection lines.

2. The multi-chip package according to claim 1, wherein each of the first group of bumps is a single stud bump.

3. The multi-chip package according to claim 1, wherein each of the second group of bumps is a single soldering bump.

4. The multi-chip package according to claim 1, wherein each of the second group of bumps includes a plurality of stacked stud bumps.

5. The multi-chip package according to claim 1, further comprising epoxy resin that fills a space between a topmost flip chip of the plurality of flip chips and the printed circuit board, wherein the epoxy resin, the plurality of flip chips and the first and second groups of bumps constitute an upper multi-chip package.

6. The multi-chip package according to claim 5, further comprising at least one adhesive that fills the space between the lowest flip chip of the plurality of flip chips and the printed circuit board and spaces between the flip chips of the plurality of flip chips.

7. The multi-chip package according to claim 5, further comprising a lower multi-chip package formed on a backside surface of the printed circuit board, wherein the lower multi-chip package has the same configuration as the upper multi-chip package.

8. The multi-chip package according to claim 1, further comprising an epoxy molding compound that encapsulates the plurality of flip chips and the first and second groups of bumps, wherein the epoxy molding compound covers the topmost flip chip of the plurality of flip chips, and the epoxy molding compound, the plurality of flip chips, and the first and second groups of bumps constitute an upper multi-chip package.

9. The multi-chip package according to claim 8, further comprising at least one adhesive that fills the space between the lowest flip chip of the plurality of flip chips and the printed circuit board and spaces between the flip chips of the plurality of flip chips.

10. The multi-chip package according to claim 8, further comprising a lower multi-chip package formed on a backside surface of the printed circuit board, wherein the lower multi-chip package has the same configuration as the upper multi-chip package.

11. The multi-chip package according to claim 1, further comprising:
a third chip stacked on the topmost flip chip of the plurality of flip chips, the third chip having pads formed on an opposite surface to the plurality of flip chips; and
bonding wires, electrically connecting the pads of the third chip to a third group of interconnection lines of the plurality of interconnection lines.

12. The multi-chip package according to claim 11, further comprising an epoxy molding compound that encapsulates the plurality of flip chips, the third chip, the first and second groups of bumps and the bonding wires, wherein the epoxy molding compound covers the third chip, and the epoxy molding compound, the plurality of flip chips, the third chip, the first and second groups of bumps and the bonding wires constitute an upper multi-chip package.

13. The multi-chip package according to claim 11, further comprising at least one adhesive that fills a space between the plurality of flip chips, a space between the lowest flip chip of the plurality of flip chips and the printed circuit board, and a space between the topmost flip chip of the plurality of flip chips and the third chip.

14. The multi-chip package according to claim 12, further comprising a lower multi-chip package formed on a backside surface of the printed circuit board, wherein the lower multi-chip package has the same configuration as the upper multi-chip package.

15. A multi-chip package comprising:
a printed circuit board including a substrate, and a first group of interconnection lines and a second group of interconnection lines formed on a surface of the substrate;
a lower flip chip and an upper flip chip stacked on the surface of the substrate, the lower flip chip and the upper flip chip including pads facing the printed circuit board;
a first group of bumps interposed between the pads of the lower flip chip and the first group of interconnection lines;
a second group of bumps interposed between the pads of the upper flip chip and the second group of interconnection lines; and
an epoxy resin filling a space between the upper flip chip and the printed circuit board.

16. The multi-chip package according to claim 15, wherein each of the first group of bumps is a single stud bump.

17. The multi-chip package according to claim 15, wherein each of the second group of bumps is a single soldering bump.

18. The multi-chip package according to claim 15, wherein each of the second group of bumps has a plurality of stacked stud bumps.

19. The multi-chip package according to claim 15, further comprising at least one adhesive filling a space between the lower flip chip and the printed circuit board and a space between the upper flip chip and the lower flip chip.

20. The multi-chip package according to claim 15, wherein the upper flip chip is positioned to cross over the lower flip chip to form overhangs that do not overlap the lower flip chip, and the second group of bumps are interposed between the overhangs and the second group of interconnection lines.

21. The multi-chip package according to claim 15, wherein the upper flip chip has a greater planar area than the lower flip chip.

22. A multi-chip package comprising:
a printed circuit board including a substrate, and a first group of interconnection lines and a second group of interconnection lines formed on a surface of the substrate;
a lower flip chip and an upper flip chip stacked on the surface of the substrate, the lower and upper flip chips including pads facing the printed circuit board;
a first group of bumps interposed between the pads of the lower flip chip and the first group of interconnection lines;
a second group of bumps interposed between the pads of the upper flip chip and the second group of interconnection lines; and
an epoxy molding compound encapsulating the lower and upper flip chips and the first and second groups of bumps, the epoxy molding compound covering the upper flip chip.

23. The multi-chip package according to claim 22, wherein each of the first group of bumps is a single stud bump.

24. The multi-chip package according to claim 22, wherein each of the second group of bumps is a single soldering bump.

25. The multi-chip package according to claim 22, wherein each of the second group of bumps has a plurality of stacked stud bumps.

26. The multi-chip package according to claim 22, further comprising at least one adhesive filling a space between the lower flip chip and the printed circuit board and a space between the upper flip chip and the lower flip chip.

27. The multi-chip package according to claim 22, further comprising:
a third chip stacked on the upper flip chip, the third chip having pads formed on an opposite surface to the lower and upper flip chips; and
bonding wires electrically connecting the pads of the third chip to a third group of interconnection lines on the printed circuit board, wherein the epoxy molding compound covers the third chip and the bonding wires.

28. The multi-chip package according to claim 27, further comprising an adhesive interposed between the upper flip chip and the third chip.

29. The multi-chip package according to claim 22, wherein the upper flip chip is stacked to cross over the lower flip chip to form overhangs that do not overlap the lower flip chip, and the second group of bumps are interposed between the overhangs and the second group of interconnection lines.

30. The multi-chip package according to claim 22, wherein the upper flip chip has a greater planar area than the lower flip chip.

31. A method, comprising:
providing a printed circuit board including a substrate and a plurality of interconnection on a surface of the substrate;
stacking a plurality of flip chips on the surface of the printed circuit board, wherein a lowest flip chip has pads facing the printed circuit; and
interposing a first group of bumps between the pads of the lowest flip chip and first interconnection lines of the plurality of interconnection lines; and
interposing a second group of bumps between the pads of the at least one upper flip chip and second interconnection lines of the plurality of interconnection lines.

32. A method, comprising:
providing a printed circuit board including a substrate, a first group of interconnection lines and a second group of interconnection lines formed on a surface of the substrate;
stacking a lower flip chip and an upper flip chip on the surface of the substrate, the lower flip chip and the upper flip chip including pads facing the printed circuit board;
interposing a first group of bumps between the pads of the lower flip chip and the first group of interconnection lines;
interposing a second group of bumps between the pads of the upper flip chip and the second group of interconnection lines; and
filling a space between the upper flip chip and the printed circuit board with an epoxy resin.

33. A method, comprising:
providing a printed circuit board including a substrate, a first group of interconnection lines and a second group of interconnection lines on a surface of the substrate;
stacking a lower flip chip and an upper flip chip on the surface of the substrate, the lower and upper flip chips including pads facing the printed circuit board;
interposing a first group of bumps between the pads of the lower flip chip and the first group of interconnection lines;
interposing a second group of bumps between the pads of the upper flip chip and the second group of interconnection lines; and
encapsulating the lower and upper flip chips and the first and second groups of bumps with an epoxy molding compound such that the epoxy molding compound covers the upper flip chip.

34. A multi-chip package manufactured by the method of claim 31.

35. A multi-chip package manufactured by the method of claim 32.

36. A multi-chip package manufactured by the method of claim 33.
